(19) United States
(12) Patent Application Publication
(10) Pub. No.: US 2024/0404906 A1
(43) Pub. Date: Dec. 5, 2024

(54) SEMICONDUCTOR DEVICE

(71) Applicant: FUJI ELECTRIC CO., LTD., Kawasaki-shi (JP)

(72) Inventor: Shingo HAYASHI, Matsumoto-shi (JP)

(73) Assignee: FUJI ELECTRIC CO., LTD., Kawasaki-shi (JP)

(21) Appl. No.: 18/592,974

(22) Filed: Mar. 1, 2024

(30) Foreign Application Priority Data
May 30, 2023 (JP) 2023-088707

(51) Int. Cl. H01L 23/31; H01L 29/16; H01L 29/78

(52) U.S. Cl. CPC H01L 23/3171; H01L 23/3192; H01L 29/1608; H01L 29/7811

(57) ABSTRACT

A semiconductor device includes an active region, which is a region where main current flows, an edge termination region surrounding the active region, a step surface surrounding the edge termination region, and a dicing line surrounding the step surface. The active region has a first pn junction of a first semiconductor region and a second semiconductor layer and a second pn junction of an outer peripheral region and the second semiconductor layer. The step surface is provided with a first protective film for shielding light generated as forward current flows through the first and second pn junctions in the active region.

### CROSS-REFERENCE TO RELATED APPLICATION(S)

This application is based on and claims priority under 35 USC 119 from Japanese Patent Application No. 2023-088707 filed on May 30, 2023, the contents of which are incorporated herein by reference.

### TECHNICAL FIELD

The present invention relates to a semiconductor device.

### BACKGROUND ART

In a semiconductor device using a wide band gap semiconductor, known is a semiconductor device having a functional region provided between a semiconductor chip and a sealing resin to block light with a specific wavelength that deteriorates the sealing resin in order to prevent deterioration of the sealing resin due to light generated at a pn junction of the semiconductor chip. For example, Japanese Patent No. 6892997B is published.

An object is to provide a semiconductor device that can suppress deterioration of a sealing resin at an end portion on a chip side due to light generated by recombination of electrons and holes in a semiconductor chip.

### SUMMARY

In order to solve the above problems and to achieve the object of the present invention, a semiconductor device according to the present invention has following features.

The semiconductor device includes a semiconductor substrate made of a wide band gap semiconductor and having a first principal surface and a second principal surface; an active region provided in a central portion when viewed from the first principal surface side of the semiconductor substrate; an edge termination region provided to surround the active region; and a dicing line provided to surround the edge termination region, in which the active region has at least one junction of different conductivity types having a first conductivity-type region and a second conductivity-type region, in which a step surface provided on the first principal surface side between the edge termination region and the dicing line so as to be on the second principal surface side with respect to the junction of different conductivity types is provided, and in which the step surface is covered with a first protective film having a low light transmittance.

The active region is a MOS-type semiconductor device with an insulated gate, the first conductivity-type region is a drift region, and the second conductivity-type region is a base region.

The first protective film is provided on the first principal surface side of the edge termination region, in addition to the step surface.

The first protective film has a light transmittance of 5% or less in a visible light wavelength region.

The first protective film has a transmittance of 5% or less of visible light with a shorter wavelength than blue.

The first protective film has a transmittance of 5% or less of ultraviolet light.

The first protective film is an organic film made of polyimide.

The first protective film is an inorganic film made of non-doped polysilicon or amorphous silicon.

The first protective film has a film thickness of 10 μm or greater.

On the step surface, a second protective film is further provided between the semiconductor substrate and the first protective film.

The second protective film has a film thickness of 10 μm or greater. The second protective film is an organic film formed of polyimide or the like.

The second protective film is an inorganic film of non-doped polysilicon, amorphous silicon or the like.

According to the above invention, in the semiconductor device, the step surface is formed between the edge termination region where a breakdown voltage structure is provided and the dicing line provided to surround the edge termination region. The step surface is provided with the first protective film to block light generated in the semiconductor device. The light generated in the semiconductor device is mainly emitted from a drift region of a chip side surface. Therefore, at least the first protective film is provided to cover the drift region on the chip side surface side, so that deterioration in characteristics of a sealing resin or gel on the chip side surface side can be prevented, which can improve the reliability of the semiconductor device.

According to the semiconductor device of the present invention, it is possible to suppress deterioration of a sealing resin due to light generated by recombination of electrons and holes in a semiconductor chip.

### BRIEF DESCRIPTION OF DRAWINGS

FIG. 1 is a cross-sectional view showing a structure of a semiconductor device according to a first embodiment.

FIG. 2 is a cross-sectional view showing another aspect of the semiconductor device according to the first embodiment.

FIG. 3 is a cross-sectional view showing a structure of a semiconductor device according to a second embodiment.

FIG. 4 is a cross-sectional view showing another aspect of the semiconductor device according to the second embodiment.

FIG. 5 is a cross-sectional view showing a structure of a semiconductor device according to a third embodiment.

FIG. 6 is a cross-sectional view showing a structure of a semiconductor device according to Comparative Example.

### DESCRIPTION OF EMBODIMENTS

Hereinafter, preferred embodiments of a semiconductor device according to the present invention will be described with reference to the accompanying drawings. In the specification and accompanying drawings, a layer or region denoted with n or p means that majority carriers of the layer or region are electrons or holes, respectively. In addition, “+” and “−” attached to “n” and “p” mean that impurity concentrations are higher and lower than a layer and a region without “+” and “−”, respectively. Cases where denotations of n and p including “+” and “−” are the same indicate that concentrations are close, and therefore, the concentrations are not necessarily equal. Note that, in the description of the embodiments below and the accompanying drawing, the similar configurations are denoted with the same reference numerals, and will not be redundantly described.

In the present specification, one side of a direction parallel to a depth direction of a semiconductor substrate is called “up”, the other side is called “down” and a direction perpendicular to the depth direction of the semiconductor substrate is called “lateral direction”. One surface of two principal surfaces of a substrate, a layer or another member is called “upper surface”, and the other surface is called “lower surface.” The “upper” and “lower” directions are not limited to a gravity direction or a direction at the time of mounting a semiconductor device.

A region from a center in the depth direction of the semiconductor substrate to the upper surface of the semiconductor substrate may be referred to as the upper surface side. Similarly, a region from the center in the depth direction of the semiconductor substrate to the lower surface of the semiconductor substrate may be referred to as the lower surface side.

As used herein, the description “equal” or “same” may include an error due to manufacturing variation and the like. The error is, for example, within 10%.

### First Embodiment

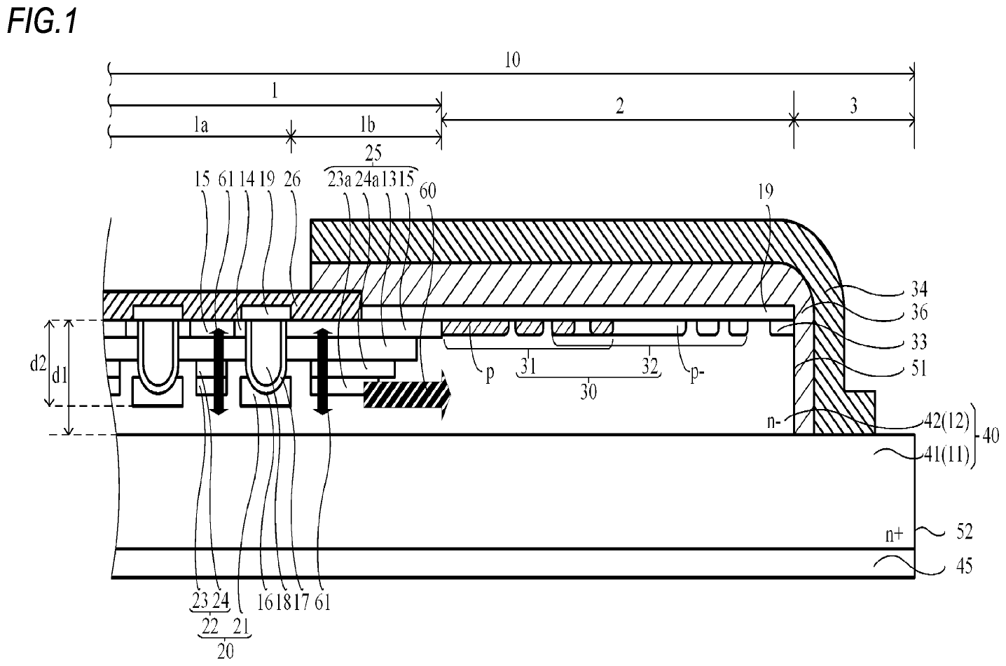

A structure of a semiconductor device according to a first embodiment will be described. FIG. 1 is a cross-sectional view showing a structure of a semiconductor device 10 according to a first embodiment. As an example, the semiconductor device 10 is a MOSFET. The semiconductor device 10 has a semiconductor substrate 40 made of a wide band gap semiconductor with a band gap wider than silicon (Si), and includes an active region 1, an edge termination region 2, and a dicing line 3 in the semiconductor substrate 40.

The semiconductor substrate 40 is made of silicon carbide, for example. The semiconductor substrate 40 includes an n⁺-type starting substrate 41 and an n⁻-type silicon carbide layer 42 formed in contact with the n⁺-type starting substrate 41. The semiconductor substrate 40 has, as a front surface (first principal surface), a principal surface on the n⁻-type silicon carbide layer 42 side, and, as a back surface (second principal surface), a principal surface on the n⁺-type starting substrate 41 side. Furthermore, in the semiconductor device 10, the n⁺-type starting substrate 41 becomes an n⁺-type drain region 11, and the n⁻-type silicon carbide layer 42 becomes an n⁻-type drift region 12.

The active region 1 is provided substantially at a center of the semiconductor substrate 40, and the edge termination region 2 is provided to surround an outer periphery of the active region 1. In addition, the dicing line 3 is provided to surround an outer periphery of the edge termination region 2 and terminates at a chip end portion 52 located laterally opposite to the active region 1.

The semiconductor substrate 40 may be substantially flat over an entire front surface of the active region 1 and the edge termination region 2. The description “substantially flat” means that a surface is horizontal within a range that includes a tolerance due to process variation.

In the active region 1, a central portion 1a of the active region is provided in which a plurality of unit cells of the same mechanism (element structure) of the MOSFET are arranged adjacent to each other. The central portion 1a of the active region is a region where main current (drift current) flows when the MOSFET is turned on. Additionally, a peripheral portion 1b of the active region is provided to surround the central portion 1a of the active region. The peripheral portion 1b of the active region is a region for suppressing hole current concentration in the edge termination region 2 when the semiconductor device 10 is turned off, and a plurality of unit cells of the same mechanism (element structure) of the MOSFET are not provided.

In the active region 1, a p-type base region 13 is provided to be in contact with the first principal surface and the n⁻-type drift region 12 inside the semiconductor substrate 40. The p-type base region 13 may be provided throughout the entire region between the front surface of the semiconductor substrate 40 and the n⁻-type drift region 12.

A trench gate structure is provided in the central portion 1a of the active region. The trench gate structure is a structure in which a plurality of identical unit cells each composed of a p-type base region 13, an n⁺-type source region 14, a p⁺⁺-type contact region 15, a trench 16, a gate insulating film 17, and a gate electrode 18 are arranged and connected. The p-type base region 13, the n⁺-type source region 14, and the p⁺⁺-type contact region 15 are diffusion regions formed inside the n⁻-type silicon carbide layer 42 by ion implantation.

The n⁺-type source region 14 and the p⁺⁺-type contact region 15 are each selectively provided between the front surface of the semiconductor substrate 40 and the p-type base region 13, and are in contact with the p-type base region 13 on the second principal surface side (lower surface side). The n⁺-type source region 14 is provided in contact with the p⁺⁺-type contact region 15 in the central portion 1a of the active region. The n⁺-type source region 14 and the p⁺⁺-type contact region 15 are in contact with a source electrode 26 on the front surface side.

In the active region 1, an interlayer insulating film 19 is provided to be in contact with the front surface of the semiconductor substrate 40.

The source electrode 26 is provided on the interlayer insulating film 19 to fill a contact hole of the interlayer insulating film 19. The source electrode 26 may be provided 25 throughout the central portion 1a of the active region, and the source electrode 26 is electrically connected to the n⁺-type source region 14, the p⁺⁺-type contact region 15, the p-type base region 13, and the p⁺-type regions 21 and 22.

Between the p-type base region 13 and the n⁻-type drift region 12, at a position deeper on the n⁺-type drain region 11 side (second principal surface side) than a bottom surface of the 30 trench 16, a p⁺-type region 21 below the trench (hereinafter, referred to as p⁺-type region 21) and a p⁺-type region 22 between the gate electrodes (hereinafter, referred to as p⁺-type region 22) are selectively provided.

The p⁺-type region 21 may be in contact with the gate insulating film 17 at the bottom surface of the trench 16 or may be spaced apart from the bottom surface of the trench 16. A width of the p⁺-type region 21 may be the same as a width of the trench 16, or may be greater than the width of the trench 16.

The p⁺-type region 22 is provided between the adjacent trenches 16 and spaced apart from the p⁺-type region 21 and the trench 16. The p⁺-type region 22 is in contact with the p-type base region 13 on its upper surface, and is electrically connected to the source electrode 26 via the p-type base region 13. The p⁺-type region 22 may be formed as two layers where an upper p⁺-type region 24 formed on the front surface side inside the n⁺-type silicon carbide layer 42 and a lower p⁺-type region 23 formed on the lower surface side inside the n⁻-type silicon carbide layer 42 are adjacent in a depth direction, or may be one layer where the upper and lower p+-type regions are formed simultaneously.

The p⁺-type regions 21 and 22 are fixed to a potential of the source electrode 26 and are depleted when the semiconductor device 10 is turned off, thereby alleviating an electric field applied to the gate insulating film 17. The p⁺-type region 21 is provided spaced apart from the p-type base region 13 and faces the bottom surface of the trench 16 in the depth direction. Additionally, the p⁺-type region 21 has a portion that is connected to the p⁺-type region 22 in a portion (not shown), and is electrically connected to the source electrode 26.

The n⁻-type drift region 12 is in contact with the p-type base region 13 and the p⁺-type regions 21 and 22, and may also be in contact with the gate insulating film 17 of the trench 16.

The semiconductor device 10 may be provided with an n⁻-type current spreading region (not shown) that reduces carrier spread resistance at a position deeper on the n⁺-type drain region 11 side than the bottom surface of the trench 16, between the p-type base region 13 and the n⁻-type drift region 12. The n-type current spreading region may reach a position deeper on the n⁺-type drain region 11 side than the p⁺-type regions 21 and 22.

When the n-type current spreading region is provided, it is in contact with the p⁺-type regions 21 and 22 between the p⁺-type regions 21 and 22 adjacent to each other, extends in a direction parallel to the front surface of the semiconductor substrate 40 to reach the trench 16, and is in contact with the gate insulating film 17. Additionally, the n⁻-type current spreading region is in contact with the p-type base region 13 on the front surface side, and is in contact with the n⁻-type drift region 12 on the lower surface side.

The p⁺-type regions 21 and 22 reach the n⁻-type drift region 12 (n-type current spreading region when the n-type current spreading layer is provided) on the lower surface side, and form a first pn junction (built-in diode 61). When forward current flows through the first pn junction (built-in diode 61), electrons and holes recombine, and blue light 60 (including ultraviolet light with a shorter wavelength than blue) is generated.

The peripheral portion 1b of the active region is a region surrounding the central portion 1a of the active region in a substantially rectangular shape in the active region 1, and refers to a region on the chip end portion 52 side with respect to an outer side of the unit cell of the MOSFET provided on the outermost side of the central portion 1a of the active region.

In the peripheral portion 1b of the active region, a p-type contact region 15, a p-type base region 13, a p-type extension region 24a, and a p-type extension region 23a are provided adjacent in the depth direction from the front surface of the semiconductor substrate inside the n⁻-type drift region 42. These regions are extended regions of the p⁻⁻-type contact region 15, the p-type base region 13, the lower p⁺-type region 23 between the gate electrodes, and the upper p⁺-type region 24 between the gate electrodes in the central portion 1a of the active region. In the plurality of p-type regions, a p-type outer peripheral region 25 is formed between the front surface of the n⁻-type silicon carbide layer 42 and the n⁻-type drift region 12.

The p-type outer peripheral region 25 in the peripheral portion 1b of the active region may be formed to surround the central portion 1a of the active region. The p-type outer peripheral region 25 is a region for pulling out the Hall current, which occurs in the n⁻-type drift region 12 of the edge termination region 2 and flows toward the active region 1 when the semiconductor device 10 is turned off, to the source electrode 26. The hole current, which occurs in the edge termination region 2 when the MOSFET is turned off, is pulled out to the source electrode 26 via the p-type outer peripheral region 25, so that the concentration of hole current in the edge termination region 2 upon avalanche breakdown is suppressed.

The p-type outer peripheral region 25 forms a second pn junction (built-in diode 61) with the n⁻-type drift region 12. When forward current flows through the second pn junction (built-in diode 61), electrons and holes combine, and blue light 60 is generated.

The edge termination region 2 is provided at the outer periphery of the active region 1 of the semiconductor substrate 40, and is a region from which the p⁺⁺-type contact region 15, the p-type base region 13, and the n⁻-type source region 14 have been removed. Additionally, in the edge termination region 2, an interlayer insulating film 19 is formed to be in contact with the front surface of the semiconductor substrate 40.

In the edge termination region 2, a breakdown voltage structure 30 for alleviating an electric field on the upper surface side of the semiconductor substrate 40 is provided. For the breakdown voltage structure 30, a breakdown voltage structure such as a p-type region configuring a junction termination extension (JTE) structure, a guard ring, a field plate, or a RESURF may be provided. In this description, for example, the JTE structure is a spatial modulation JTE structure, and is composed of a plurality of p-type regions 31 and a plurality of p⁻-type regions 32 selectively provided on the front surface of the semiconductor substrate 40. The plurality of p-type regions 31 and the plurality of p-type regions 32 are diffusion regions formed in the surface region of the n⁻-type silicon carbide layer 42 by ion implantation.

The plurality of p-type regions 31 are arranged concentrically surrounding the active region 1 and spaced apart from each other. The p-type region 31 arranged on a further outer side has a narrower width (lateral width from the inner side toward the outer side of the semiconductor device) and a wider gap with the p-type region 31 adjacent on the inner side. The innermost p-type region 31 is arranged adjacent to the outer side of the p⁺⁺-type contact region 15.

The plurality of p⁻-type regions 32 are arranged concentrically surrounding the active region 1 and spaced apart from each other. The p⁻-type region 32 arranged on a further outer side has a narrower width (lateral width) and a wider gap with the p⁻-type region 32 adjacent on the inner side. A width of the outermost p⁻-type region 32 may be greater than a width of the p⁻-type region 32 adjacent on the inner side. A width of the innermost p-type region 32 is arranged between all the p-type regions 31 adjacent to each other, is adjacent to the p-type regions 31 on both sides in the lateral direction, and surrounds corner portions of bottoms of all the p-type regions 31.

An inner-side end portion of the innermost p-type region 32 is at the same position as an inner-side end portion of the innermost p-type region 31, or terminates on a further outer side than the inner-side end portion of the innermost p-type region 31. The p⁻-type regions 32 other than the innermost p⁻-type region 32 are arranged outside the p-type region 31. The n⁻-type drift region 12 extends between all the p⁻-type regions 32 adjacent to each other to reach the front surface of the semiconductor substrate 40 and is adjacent to the p⁻-type regions 32 on both sides in the lateral direction.

Additionally, an n⁺-type channel stopper region 33 is provided on the chip end portion 52-side with respect to the breakdown voltage structure 30 in the front surface of the semiconductor substrate 40. The n⁺-type channel stopper region 33 is a diffusion region formed in the surface region of the n⁻-type silicon carbide layer 42 by ion implantation. The n⁺-type channel stopper region 33 is provided spaced apart from the breakdown voltage structure 30 and is provided to surround the breakdown voltage structure 30.

The n⁺-type channel stopper region 33 has a floating potential, and is in contact with the n⁻-type silicon carbide layer 42 on a lower surface side thereof and is in contact with the interlayer insulating film 19 on an upper surface side thereof. In the edge termination region 2, a p⁺-type channel stopper region may be provided instead of the n⁺-type channel stopper region 33.

In the edge termination region 2, the interlayer insulating film 19 is formed to be in contact with the front surface of the semiconductor substrate 40.

The dicing line 3 is provided at an outer periphery of the edge termination region 2 in the semiconductor substrate 40. A front surface of the dicing line 3 is provided to be substantially flat on the second principal surface side with respect to the front surface of the edge termination region 2, and a step surface 51 is formed at a boundary between the edge termination region 2 and the dicing line 3 so that the n⁻-type silicon carbide layer 42 and the n⁺-type channel stopper region 33 are exposed on a semiconductor chip side surface side (chip end portion 52 side).

The step surface 51 may be perpendicular to the front surface of the edge termination region 2, and is provided so that the n⁺-type channel stopper region 33 and the n⁻-type silicon carbide layer 42 are exposed. The deepest portion of the step surface 51 is provided to terminate within the n⁻-type silicon carbide layer 42 or to reach an interface between the n⁺-type starting substrate 41 and the n⁻-type silicon carbide layer 42. Additionally, the front surface of the dicing line 3 is provided at the same depth as the step surface 51.

A first protective film 34 (opaque protective film) may be formed so as to be in contact with the entire surface (a region where the n⁺-type channel stopper region 33 and the n⁻-type silicon carbide layer 42 are exposed) of the step surface 51. Here, ‘opaque’ means shielding the blue light 60 and not transmitting the same, and the blue light 60 directed to the outside of the semiconductor device can be prevented from leaking to the outside of the semiconductor device.

The first protective film 34 is, for example, a black protective film and is formed of a black polyimide film as an organic film. ‘Black’ means not transmitting light including the blue light 60.

Here, ‘not transmitting light’ means that a light transmittance of the first protective film 34 in the visible light wavelength region (400 nm to 780 nm) is a prescribed value or less. The first protective film 34 may have a light transmittance of 5% or less, preferably 3% or less, and more preferably 1% or less in the visible light wavelength range.

By setting the light transmittance of the first protective film 34 in the visible light wavelength region to 5% or less, the blue light 60 generated inside the semiconductor device can be suppressed from leaking to the outside of the semiconductor device.

The blue light 60 generated inside the semiconductor device includes at least light in a region (400 nm to 490 nm) with a shorter wavelength than blue of visible light. Therefore, the first protective film 34 preferably has a low light transmittance with a shorter wavelength than blue of visible light. The first protective film 34 preferably has a light transmittance of 5% or less with a shorter wavelength than a blue wavelength region of visible light, preferably 3% or less, and more preferably 1% or less.

Additionally, the blue light 60 generated inside the semiconductor device includes ultraviolet light (390 nm peak) with a shorter wavelength than visible light. Therefore, the first protective film 34 preferably has a low transmittance of ultraviolet light (400 nm or less) with a shorter wavelength than visible light. The transmittance of ultraviolet light is, for example, 5% or less, preferably 3% or less, and more preferably 1% or less.

The black polyimide film may be formed by injecting oxygen (O₂) into polyimide. Additionally, the black polyimide film may be formed by setting a cure temperature to 400° C. or higher after applying polyimide. Furthermore, the black polyimide film may be a photosensitive film into which oxygen has not been injected, and may be formed to have a thickness of 15 μm or greater.

The black polyimide film may be formed by adding carbon black or titanium black to polyimide.

Additionally, a second protective film 36 (translucent protective film) may be provided between the surface of the step surface 51 and the first protective film 34 (opaque protective film). As used herein, ‘translucent’ means transmitting all or a part of the blue light 60 without completely shielding at least the blue light 60.

The second protective film 36 may be an organic film made of polyimide or the like. Here, for example, a translucent polyimide film is formed.

As described above, the second protective film 36 transmits at least a part of the blue light 60 generated inside the semiconductor device 10. Therefore, in order to prevent the blue light 60 from leaking to the outside of the semiconductor device 10, it is necessary to provide the first protective film 34 (opaque protective film) on a surface of the second protective film 36 (translucent protective film).

The first protective film 34 and the second protective film 36 may be, for example, an inorganic film such as a non-doped polysilicon film or an amorphous silicon film, respectively. Since it is good for the non-doped polysilicon film to have high resistance, the non-doped polysilicon film does not need to be completely non-doped. For example, a net amount of impurities is preferably 1×10¹⁵/cm³ or less. In addition, the first and second protective films are preferably formed to have a thickness of 10 μm or greater in order to ensure insulation, and are preferably formed to have a thickness of 20 μm or less in order to improve patterning precision.

The blue light 60 generated from the built-in diode 61 in the peripheral portion 61b of the active region mainly travels parallel to the surface of the semiconductor substrate in the lateral direction from the inner side toward the outer side of the semiconductor device, and leaks outside from the side surface (step surface 51) of the n⁻-type silicon carbide layer 42.

A depth from the front surface of the n⁻-type silicon carbide layer 42 in the edge termination region 2 to the deepest portion of the step surface 51 (position where the dicing line 3 is exposed) is denoted as d1, and a distance in a depth direction (direction perpendicular to the front surface of the semiconductor substrate 40) from the front surface of the n⁻-type silicon carbide layer 42 to any one, which is formed at a position close to the second principal surface side of the semiconductor substrate 40, of the first pn junction and the second pn junction is denoted as d2. Since the blue light 60 is generated from the interface of the pn junction and travels in the lateral direction, the depth d1 of the step surface 51 is preferably set greater than d2. For example, in the case of a MOSFET having a trench gate structure, a trench depth is often set to about 1 μm, and the blue light 60 occurs as holes injected from the p-type region 20, which protects the electric field applied to the trench, recombine with electrons until reaching an n⁺ region that is a substrate. For this reason, the depth of the step surface 51 is preferably at least 1 μm or greater.

Since the blue light 60 is generated between the p-type region 20 and the n⁺-type starting substrate 41 as described above, and mainly leaks from the side surface of the n⁻-type silicon carbide layer 42, the depth d1 of the step surface 51 is more preferably set to be same as a distance from the front surface of the n⁻-type silicon carbide layer 42 to the interface between the n⁻-type silicon carbide layer 42 and the n⁺-type starting substrate 41.

By setting the depth at which the step surface 51 is formed as described above and forming the first protective film 34 on the surface side of the step surface 51, it becomes possible to block the blue light 60 leaking from the step surface 51.

The first protective film 34 is preferably provided at least on the surface of the step surface 51. Furthermore, the first protective film 34 is also preferably provided on the interlayer insulating film 19 in the edge termination region 2. Thereby, the leakage of the blue light 60 from the front surface of the edge termination region 2 of the semiconductor device 10 can be suppressed.

The first protective film 34 may be provided extending toward the chip end portion 52 side so as to be in contact with the dicing line 3 (a region which is close to the chip end portion 52 side with respect to the step surface 51 and in which the semiconductor substrate 40 is exposed substantially flat). In addition, considering the cutting of the semiconductor chip (semiconductor substrate 40), the front surface of the dicing line 3 is preferably provided with a region of about 10 to 80 μm, in which various protective films such as the interlayer insulating film 19, the first protective film 34, and the second protective film 36 are not provided, from the chip end portion 52 toward the active region 1 side.

In the active region 1 and the edge termination region 2, the second protective film 36 may be formed to be in contact with the upper surface side of the interlayer insulating film 19 in order to prevent ion diffusion into the semiconductor element and to insulate the semiconductor element.

The semiconductor device 10 is entirely covered with a sealing resin (not shown) for insulation protection. The sealing resin (not shown) may be made of a thermosetting resin composition, and is particularly preferably made of a highly heat-resistant thermosetting resin composition. The thermosetting resin composition contains a thermosetting resin main component, and may optionally contain an inorganic filler, a curing agent, a curing accelerator, and a necessary additive.

As described above, the first protective film 34 is provided at least on the surface of the step surface 51, so that the blue light 60 generated from the pn junction and traveling in the lateral direction is shielded by the first protective film 34. Thereby, the blue light 60 does not reach the sealing resin on the chip side surface side, so deterioration of the sealing resin can be suppressed. For this reason, the adhesion between the sealing resin and the first protective film 34 becomes better, and there is no characteristic deterioration in the film properties of the interlayer insulating film 19 and the like, so that the reliability of the semiconductor device 10 is improved.

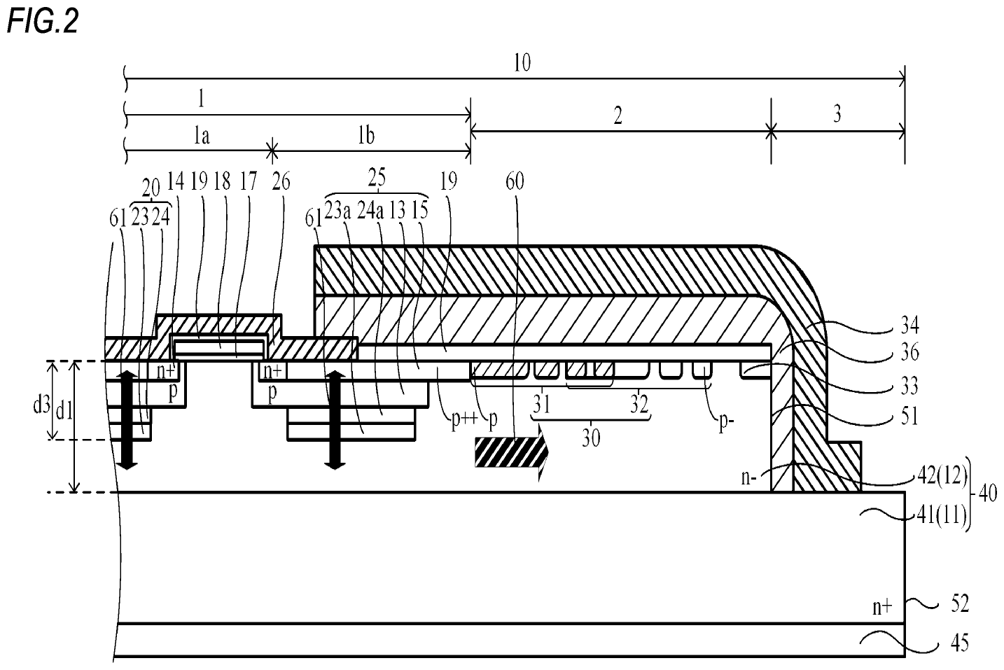

FIG. 2 shows a case where the central portion 1a of the active region has a planar gate structure, and the structures other than the active region 1 are common to the structure shown in FIG. 1. The planar gate structure is composed of a p-type base region 13, an n⁺-type source region 14, a gate insulating film 17, and a gate electrode 18. The p-type base region 13 is provided between the front surface of the semiconductor substrate 40 and the n⁻-type drift region 12 in the central portion 1a of the active region, and terminates at the peripheral portion 1b of the active region.

Between adjacent gate electrodes 18, a p⁺-type region 20 is provided to be in contact with a lower surface side of the p-type base region 13 and to terminate in the n⁻-type drift region 12. The p⁺-type region 20 is fixed to the potential of the source electrode 26 and has an effect of alleviating an electric field applied to the gate insulating film 17 by pulling out the current when the semiconductor device 10 is turned off to the source electrode 26 via the p⁺-type region 20 and the p-type base region 13.

In the peripheral portion 1b of the active region, a p⁺⁺-type contact region 15, a p-type base region 13, a p⁺-type extension region 24a, and a p⁺-type extension region 23a are provided adjacent in the depth direction from the front surface of the semiconductor substrate inside the n⁻-type drift region 12. These regions are extended regions of the p⁺⁺-type contact region 15, the p-type base region 13, the lower p⁺-type region 23 between the gate electrodes, and the upper p⁺-type region 24 between the gate electrodes in the central portion 1a of the active region. In the plurality of p-type regions, a p-type outer peripheral region 25 is formed between the front surface of the n⁻-type silicon carbide layer 42 and the n⁻-type drift region 12.

The lower surface side of the p⁺-type region 20 forms a first pn junction (built-in diode 61) with the n⁻-type drift region 12, and the lower surface side of the p-type outer peripheral region 25 forms a second pn junction (built-in diode 61) with the n⁻-type drift region 12. In the first pn junction and the second pn junction, the blue light 60 is generated when forward current flows.

A depth from the front surface of the n⁻-type silicon carbide layer 42 in the edge termination region 2 to the deepest portion of the step surface 51 (position where the dicing line 3 is exposed) is denoted as d1, and a distance in a depth direction (direction perpendicular to the front surface of the semiconductor substrate 40) from the front surface of the n⁻-type silicon carbide layer 42 to any one, which is formed at a position close to the second principal surface side of the semiconductor substrate 40, of the first pn junction and the second pn junction is denoted as d3. Since the blue light 60 is generated from the interface of the pn junction and leaks mainly in the lateral direction, the depth d1 of the step surface 51 is preferably set greater than d3.

Since the blue light 60 leaks mainly from the side surface (chip end portion 52 side) of the n⁺-type silicon carbide layer 42 as described above, the depth d1 of the step surface 51 is more preferably set to be same as a distance from the front surface of the n⁻-type silicon carbide layer 42 to the interface between the n⁻-type silicon carbide layer 42 and the n+-type starting substrate 41.

In the semiconductor device 10 according to the first embodiment, the first protective film 34 and the second protective film 36 may also be provided in the active region 1, but there is no need to provide the first and second protective films at a place where the source electrode 26 is arranged. This is because the source electrode 26 blocks the blue light 60, thereby suppressing the influence of the blue light on the sealing resin.

### Second Embodiment

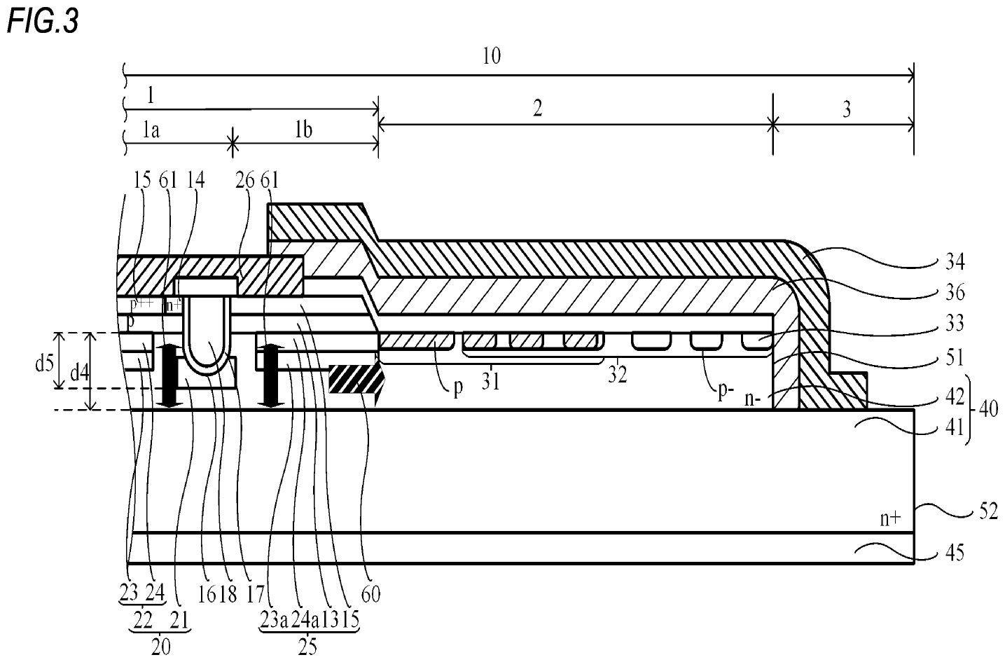

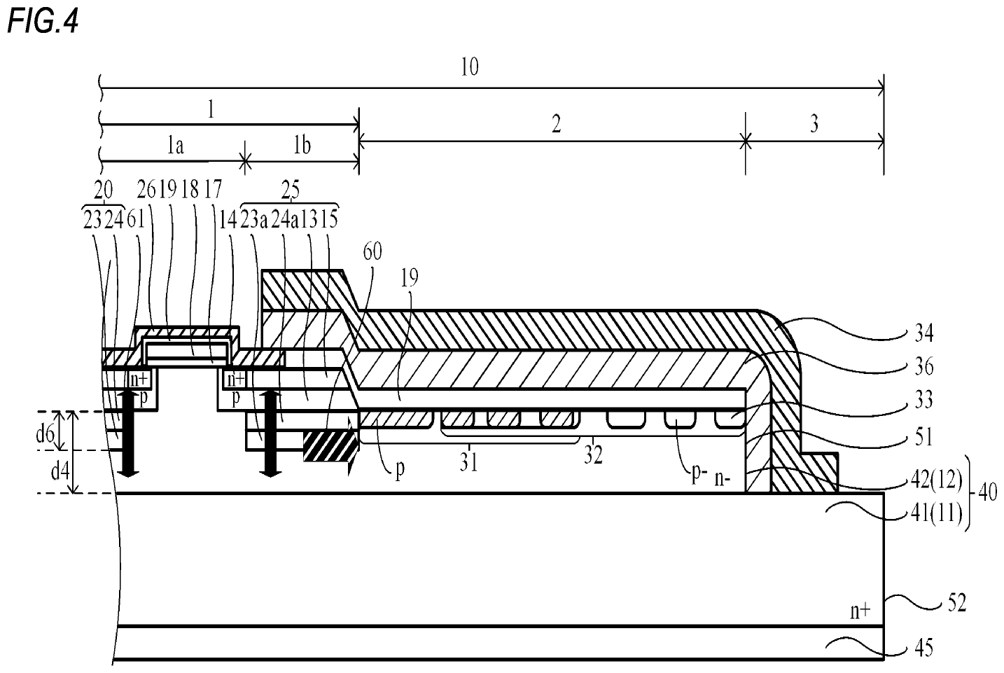

A semiconductor device according to a second embodiment will be described. FIGS. 3 and 4 are cross-sectional views showing a structure of a semiconductor device 10 according to the second embodiment. In FIGS. 3 and 4, the semiconductor device 10 is formed such that the front surface of the semiconductor substrate 40 in the edge termination region 2 is lower than the front surface of the semiconductor substrate 40 in the active region 1. The edge termination region 2 is formed lower than the active region 1 by a depth by which the p⁺⁺-type contact region 15 and the p-type base region 13 have been removed. The structure shown in FIG. 3 is similar to the semiconductor device 10 having the trench gate structure shown in FIG. 1, except for the above structure. Additionally, the structure shown in FIG. 4 is also similar to the semiconductor device 10 having a planar gate structure shown in FIG. 2, except that a step is formed between the active region 1 and the edge termination region 2.

In the semiconductor device shown in FIG. 3, a depth from the front surface of the n⁻-type silicon carbide layer 42 in the edge termination region 2 to the deepest portion of the step surface 51 (position where the dicing line 3 is exposed) is denoted as d4, and a distance in a depth direction (direction perpendicular to the front surface of the semiconductor substrate 40) from the front surface of the n⁻-type silicon carbide layer 42 to any one, which is formed at a position close to the second principal surface side of the semiconductor substrate 40, of the first pn junction and the second pn junction is denoted as d5. The depth d4 of the step surface 51 is preferably set greater than d5, and is more preferably set to be the same as a distance from the front surface of the n⁻-type silicon carbide layer 42 to the interface between the n⁻-type silicon carbide layer 42 and the n⁺-type starting substrate 41.

In the semiconductor device shown in FIG. 4, a depth from the front surface of the n⁻-type silicon carbide layer 42 in the edge termination region 2 to the deepest portion of the step surface 51 (position where the dicing line 3 is exposed) is denoted as d4, and a distance in a depth direction (direction perpendicular to the front surface of the semiconductor substrate 40) from the front surface of the n⁻-type silicon carbide layer 42 to any one, which is formed at a position close to the second principal surface side of the semiconductor substrate 40, of the first pn junction and the second pn junction is denoted as d6. The depth d4 of the step surface 51 is preferably set greater than d6, and is more preferably set to be the same as a distance from the front surface of the n⁻-type silicon carbide layer 42 to the interface between the n⁻-type silicon carbide layer 42 and the n⁺-type starting substrate 41.

### Third Embodiment

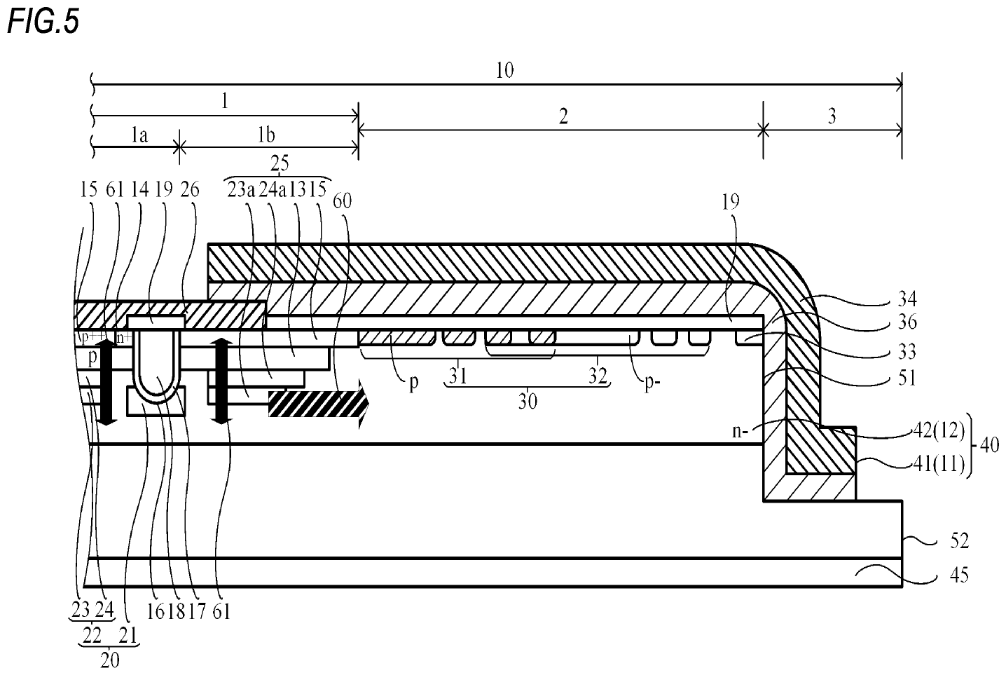

A semiconductor device according to a third embodiment will be described. FIG. 5 is a cross-sectional view showing a structure of a semiconductor device 10 according to the third embodiment. Compared to the semiconductor devices 10 shown in the first and second embodiments, the semiconductor device 10 according to the third embodiment shown in FIG. 5 has a structure in which the step surface 51 is provided deeper. In this structure, all the n⁻-type silicon carbide layer 42 is removed from the region between the step surface 51 and the chip end portion 52, and a portion of the n⁺-type starting substrate 41 is also removed.

Additionally, the semiconductor device according to third embodiment may have the same structure as the semiconductor device described in the first embodiment or may have the same structure as the semiconductor device described in the second embodiment, in the region on the active region 1 side (center side) with respect to the step surface 51. As an example, the semiconductor device shown in FIG. 5 has the same structure as the semiconductor device shown in FIG. 1, in the active region 1 and the edge termination region 2.

The step surface 51 is provided with a second protective film 36 (translucent protective film) so as to be in contact with the step surface 51, and a first protective film 34 (opaque protective film) is provided so as to be in contact with a surface of the second protective film. Alternatively, the first protective film 34 may be provided to be in contact with the step surface 51 and the second protective film 36 may not be provided.

When the deepest portion of the step surface 51 is provided on the second principal surface side with respect to the interface between the n⁻-type starting substrate 41 and the n⁻-type silicon carbide layer 42, the second protective film 36 may be provided to extend toward the chip end portion 52 side on the front surface of the dicing line 3. Additionally, the first protective film 34 may be provided to be in contact with the surface of the second protective film 36 extending to the front surface of the dicing line 3.

An upper surface (front surface) of the second protective film 36 provided to extend on the front surface of the dicing line 3 is preferably provided on the second principal surface side with respect to the interface between the n⁺-type starting substrate 41 and the n⁻-type silicon carbide layer 42. With the above structure, even when the second protective film 36 extending to the front surface of the dicing line 3 is exposed toward the chip end portion 52 side, the side surface of the n⁺-type silicon carbide layer 42 is covered by the first protective film 34, so leakage of the blue light 60 can be suppressed.

### Structure of Comparative Example

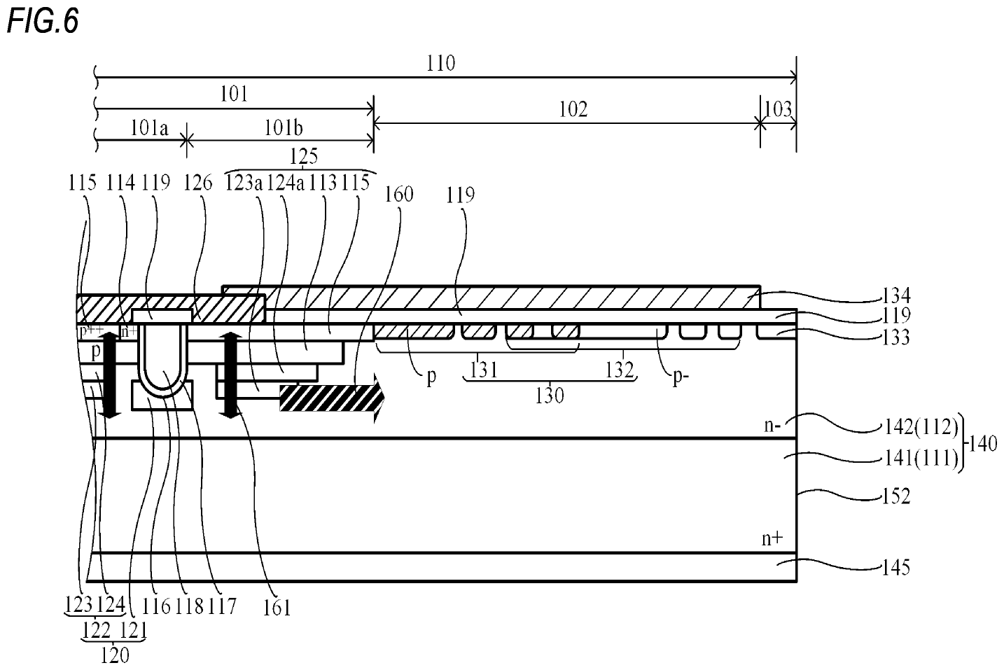

FIG. 6 is a cross-sectional view of a semiconductor device according to Comparative Example. A semiconductor device 110 according to Comparative Example has a semiconductor substrate 140 formed by an n⁺-type starting substrate 141 and an n⁻-type silicon carbide layer 142 provided to be in contact with a front surface of the n⁺-type starting substrate 141.

The semiconductor device 110 has an active region 101 provided substantially at the center of the semiconductor substrate 140, an edge termination region 102 provided to surround the active region 101, and a dicing line 103 provided to surround the edge termination region 102.

The semiconductor device 110 has a structure similar to the semiconductor device according to the present invention, except for a structure above the front surface of the semiconductor substrate 140 in the active region 101 and the edge termination region 102. This example is similar to the semiconductor device 10 having a trench gate structure shown in FIG. 1 of the first embodiment as an example.

In the semiconductor device 110, an interlayer insulating film 119 may be provided on the entire front surface of the semiconductor substrate 140. Additionally, in the active region 101 and the edge termination region 102, a protective film 134 (translucent protective film) is provided to be in contact with an upper surface side of the interlayer insulating film 119 in order to prevent ion diffusion into the semiconductor device and to insulate the semiconductor device.

The protective film 134 of the semiconductor device 110 as a comparative example is an organic film such as polyimide, or an inorganic film such as non-doped polysilicon or amorphous silicon.

In the edge termination region 102 of the semiconductor device 110, a channel stopper region 133 is selectively provided closer to a chip end portion 152 than a breakdown voltage structure 130 between the front surface of the semiconductor substrate 140 and the n⁻-type drift region 142.

The channel stopper region 133 extends from the edge termination region 102 to the chip end portion 152 of the dicing line 103 and is exposed at the chip end portion 152. Additionally, the first protective film 134 terminates on the front surface side of the n⁺-type channel stopper region 133, considering the cutting of the semiconductor device 110.

On the front surface of the semiconductor device 110, a region where the first protective film 134 is not formed between the edge termination region 102 and the chip end portion 52 is the dicing line 103.

The semiconductor device 110 has a built-in diode 161 composed of a p-type base region, an n⁻-type drift region, and the like in a central portion 101a of the active region and a peripheral portion 101b of the active region, similar to the semiconductor device according to the present invention. When a MOSFET is used as a FWD or a diode and the built-in diode is turned on, the blue light 160 is generated from the pn junction due to recombination of electrons and holes by conductivity modulation, and travels mainly in the lateral direction from the active region 101 toward the edge termination region 102. Since the interlayer insulating film 119, the channel stopper region 133, the n⁻-type drift region 142, and the n⁺-type starting substrate 141 are exposed at the chip end portion 52 of the semiconductor device 110, the blue light 160 from the n⁻-type drift region 142 easily reaches a sealing resin (not shown) provided on an outer side of the semiconductor device 110. This blue light 160 may cause deterioration of the sealing resin, degrading the adhesion between the semiconductor device 110 and the sealing resin, or the life of the sealing resin.

According to the semiconductor device according to the present invention, the step surface 51 is provided on the chip end portion 52 side with respect to the breakdown voltage structure 30 of the edge termination region 2, and the second protective film 36 (translucent protective film) and the first protective film 34 (opaque protective film) are provided on the step surface, so that leakage of the blue light 60 from the chip side surface side (chip end portion 52 side) can be suppressed. By suppressing the blue light from reaching the sealing resin, the deterioration in the adhesion between the sealing resin and the protective film and the decrease in the life of the sealing resin can be suppressed.

The present invention can be changed without departing from the spirit of the present invention, and in each of the above-described embodiments, the size of each part, the impurity concentration, and the like may be set according to required specifications. For example, as the opaque protective film, not only a polysilicon film but also an amorphous silicon film may be used, or a semiconductor with a band gap of 2 eV or less may be used. Additionally, in each embodiment, silicon carbide (SiC) has been used as the semiconductor, but instead of this, gallium nitride (GaN) or the like can also be applied. Furthermore, although the MOSFET has been exemplified in each embodiment, a semiconductor device with a pn junction, such as IGBT, a pn diode, and a Schottky barrier diode (SBD) employing a junction barrier Schottky (JBS) structure can also be applied.

### INDUSTRIAL APPLICABILITY

As described above, the semiconductor device according to the present invention is useful for power semiconductor devices used in power conversion devices, power supply devices, and the like used in industrial machines, automobiles, and the like.

1. A semiconductor device comprising:
a semiconductor substrate made of a wide band gap semiconductor and having a first principal surface and a second principal surface;
an active region provided in a central portion when viewed from the first principal surface side of the semiconductor substrate;
an edge termination region provided to surround the active region; and
a dicing line provided to surround the edge termination region,
wherein the active region has at least one junction of different conductivity types having a first conductivity type region and a second conductivity type region,
wherein a step surface provided on the first principal surface side between the edge termination region and the dicing line so as to be on the second principal surface side with respect to the junction of different conductivity types is provided, and
wherein the step surface is covered with a first protective film having a low light transmittance.

2. The semiconductor device according to claim 1, wherein the active region is a MOS-type semiconductor device with an insulated gate, the first conductivity-type region is a drift region, and the second conductivity-type region is a base region.

3. The semiconductor device according to claim 1, wherein the first protective film is provided on the first principal surface side of the edge termination region, in addition to the step surface.

4. The semiconductor device according to claim 2, wherein the first protective film is provided on the first principal surface side of the edge termination region, in addition to the step surface.

5. The semiconductor device according to claim 1, wherein the first protective film has a light transmittance of 5% or less in a visible light wavelength region.

6. The semiconductor device according to claim 2, wherein the first protective film has a light transmittance of 5% or less in a visible light wavelength region.

7. The semiconductor device according to claim 1, wherein the first protective film has a transmittance of 5% or less of visible light with a shorter wavelength than blue.

8. The semiconductor device according to claim 2, wherein the first protective film has a transmittance of 5% or less of visible light with a shorter wavelength than blue.

9. The semiconductor device according to claim 1, wherein the first protective film has a transmittance of 5% or less of ultraviolet light.

10. The semiconductor device according to claim 2, wherein the first protective film has a transmittance of 5% or less of ultraviolet light.

11. The semiconductor device according to claim 1, wherein the first protective film is an organic film made of polyimide.

12. The semiconductor device according to claim 2, wherein the first protective film is an organic film made of polyimide.

13. The semiconductor device according to claim 1, wherein the first protective film is an inorganic film made of non-doped polysilicon or amorphous silicon.

14. The semiconductor device according to claim 2, wherein the first protective film is an inorganic film made of non-doped polysilicon or amorphous silicon.

15. The semiconductor device according to claim 1, wherein the first protective film has a film thickness of 10 μm or greater.

16. The semiconductor device according to claim 2, wherein the first protective film has a film thickness of 10 μm or greater.

17. The semiconductor device according to claim 1, wherein a second protective film is further provided between the semiconductor substrate and the first protective film on the step surface.

18. The semiconductor device according to claim 2, wherein a second protective film is further provided between the semiconductor substrate and the first protective film on the step surface.

19. The semiconductor device according to claim 17, wherein the second protective film has a film thickness of 10 μm or greater.

20. The semiconductor device according to claim 17, wherein the second protective film is an organic film formed of polyimide or the like.

21. The semiconductor device according to claim 17, wherein the second protective film is an inorganic film made of non-doped polysilicon or amorphous silicon.
